(19) United States
(12) Patent Application Publication
(10) Pub. No.: US 2005/0035431 A1
(43) Pub. Date: Feb. 17, 2005

(54) Semiconductor device and method for manufacturing semiconductor device

(75) Inventor: Keita Masuda, Yokohama-shi (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: KABUSHIKI KAISHA TOSHIBA, Tokyo (JP)

(21) Appl. No.: 10/885,748

(22) Filed: Jul. 8, 2004

(30) Foreign Application Priority Data
Jul. 10, 2003 (JP) 2003-195310

(51) Int. Cl. H01L 27/082

(52) U.S. Cl. 257/565

(57) ABSTRACT

A semiconductor device includes: a collector region having a first conductivity type; an intrinsic base region having a second conductivity type provided on the collector region; an emitter region having the first conductivity type formed in an upper section of the intrinsic base region; an isolation region provided on a side of the collector region directly under the intrinsic base region; an extrinsic base region having the second conductivity type provided adjacent to the intrinsic base region, and having a higher impurity concentration than the intrinsic base region; and a base electrode region provided on the isolation region, and contacting a side of the extrinsic base region so as to have a region at the same level as the intrinsic base region.

### CROSS REFERENCE TO RELATED APPLICATIONS

This application is based upon and claims the benefit of priority from the prior Japanese Patent Applications No. P2003-195310, filed on Jul. 10, 2003; the entire contents of which are incorporated herein by reference.

### BACKGROUND OF THE INVENTION

1. Field of the Invention

The present invention relates to a semiconductor device including a bipolar junction transistor and a method for manufacturing the same.

2. Description of the Related Art

The bipolar junction transistor is known as a semiconductor device for use in high frequency applications. The bipolar junction transistor includes a collector region, an intrinsic base region provided on the collector region, and an emitter region formed in the upper section of the intrinsic base region. An extrinsic base region is provided so as to surround the intrinsic base region. A base electrode region is provided on the top of the extrinsic base region.

In order to improve the high frequency characteristics of the bipolar junction transistor, it is necessary to reduce feedback capacitance and base resistance. A method of reducing the collector junction area between the intrinsic base region and the collector region by reducing the width of the intrinsic base region is used to reduce feedback capacitance and base resistance.

However, when the collector junction area is reduced, the junction area between the extrinsic base region and the base electrode region is reduced as well, thus there is problem of increasing base resistance. That is, there is a trade-off relation between improving high frequency characteristics by reducing the collector junction area, and reducing base resistance.

### SUMMARY OF THE INVENTION

A feature of the present invention inheres in a semiconductor device including: a collector region having a first conductivity type; an intrinsic base region having a second conductivity type provided on the collector region; an emitter region having the first conductivity type formed in an upper section of the intrinsic base region; an isolation region provided on a side of the collector region directly under the intrinsic base region; an extrinsic base region having the second conductivity type provided adjacent to the intrinsic base region, and having a higher impurity concentration than the intrinsic base region; and a base electrode region provided on the isolation region, and contacting a side of the extrinsic base region so as to have a region at the same level as the intrinsic base region.

### BRIEF DESCRIPTION OF DRAWINGS

FIG. 1 is a sectional view showing an example of a semiconductor device according to an embodiment of the present invention.

FIGS. 2 to 11 are sectional views showing an example of a method for manufacturing the semiconductor device according to the embodiment of the present invention.

FIG. 12 is a sectional view showing an example of a semiconductor device according to a modification of the embodiment of the present invention.

FIG. 13 is a sectional view showing an example of a method for manufacturing the semiconductor device according to the modification of the embodiment of the present invention.

FIGS. 14 to 16 are sectional views showing examples of semiconductor devices according to other embodiment of the present invention.

FIG. 17 is a sectional view showing an example of a semiconductor device for comparing.

### DETAILED DESCRIPTION OF THE INVENTION

Various embodiments of the present invention will be described with reference to the accompanying drawings. It is to be noted that the same or similar reference numerals are applied to the same or similar parts and elements throughout the drawings, and the description of the same or similar parts and elements will be omitted or simplified.

Generally and as it is conventional in the representation of semiconductor devices, it will be appreciated that the various drawings are not drawn to scale from one figure to another nor inside a given figure, and in particular that the layer thicknesses are arbitrarily drawn for facilitating the reading of the drawings.

In the embodiment of the present invention, the “first conductivity type” and “second conductivity type” are mutual opposites. In other words, when the first conductivity type is an n-type then the second conductivity type will be a p-type, and vice versa. Below, a pnp bipolar junction transistor with the first conductivity type as an n-type and the second conductivity type as a p-type will be described as the semiconductor device according to the embodiment of the present invention. However, a pnp bipolar junction transistor with the first conductivity type as a p-type and the second conductivity type as an n-type is also contemplated.

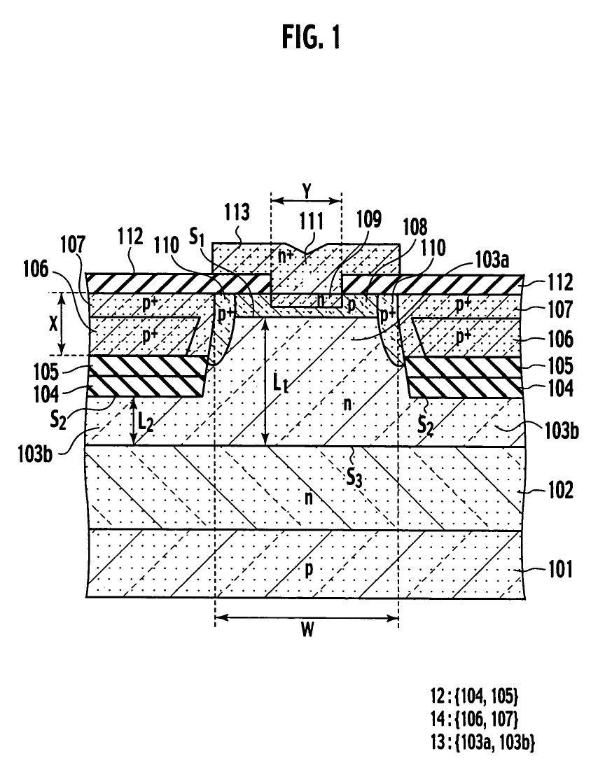

As shown in FIG. 1, a semiconductor device according to an embodiment of the present invention includes a collector region 13 having a first conductivity type (n-type), an intrinsic base region 108 having a second conductivity type (p-type) provided on the collector region 13, an emitter region 109 having the n-type formed in an upper section of the intrinsic base region 108, an isolation region 12 provided on a side of the collector region 13 directly below the intrinsic base region 108, an extrinsic base region 110 having a p⁺-type provided adjacent to the intrinsic base region 108 which has a higher impurity concentration than the intrinsic base region 108, and a base electrode region 14 provided on the top of the isolation region 12 and contacting a side of the extrinsic base region so as to have a region at the same level as the intrinsic base region 108.

The collector region 13 is provided on an n-type buried layer 102 buried in the upper section of a p-type semiconductor substrate 101. Silicon (Si), silicon germanium (SiGe) or the like may be used for the semiconductor substrate 101. The buried layer 102 is an impurity-diffused layer formed by diffusing an n-type impurity such as boron (B) in the upper section of the semiconductor substrate 101.

The collector region 13 includes a region defined by a bottom surface S₃, a first surface S₁ provided at of a first thickness L₁ from the bottom surface S₃ so as to contact the intrinsic base region 108, and a second surface S₂ provided at of a second thickness L₂, which is thinner than the first thickness L₁. That is, the collector region 13 is a convexity including a center section 103a, which contacts the bottom of the intrinsic base region 108, and a peripheral section 103b, which is thinner than the center section 103a and is adjoined to the periphery of the center section 103a. The center section 103a and the peripheral section 103b are formed of a single piece of material and contact to each other. The top of the center section 103a corresponds to the bottom of the intrinsic base region 108. The top of the peripheral section 103b corresponds to the bottom of the isolation region 12. The first thickness L₁ of the center section 103a is approximately 0.5 to 1.1 μm. The second thickness L₂ of the peripheral section 103b is approximately 0.1 to 0.5 μm. The difference between the first thickness L₁ of center section 103a and the second thickness L₂ of peripheral section 103b is approximately 0.4 to 0.6 μm.

The isolation region 12 includes a first isolation film 104 provided on the top (second surface) L₂ of the peripheral section 103b and in contact with the side of the center section 103a, and a second isolation film 105 provided on the first isolation film 104 and in contact with the side of the center section 103a. The first and second isolation films 104 and 105 have a thickness of approximately 0.4 to 0.6 μm respectively.

The base electrode region 14 has a thickness of approximately 0.2 to 0.4 μm. The base electrode region 14 includes a first base electrode region 106 provided on part of the top of the second isolation film 105 and being separated from the extrinsic base region 110, and a second base electrode region 107 provided on the remaining part of the top of the second isolation film 105 and the top of the first base electrode region 106, and in contact with the extrinsic base region 110. The second base electrode region 107 is at the same level region as the intrinsic base region 108. Both the first and second base electrode regions 106 and 107 are p⁺-type impurity diffused layers having a higher impurity concentration than the extrinsic base region 110. Each of the first and second base electrode regions 106 and 107 has a thickness of approximately 0.1 to 0.2 μm. Both the first and second base electrode regions 106 and 107 has a bottom provided at a location that is deeper than the bottom of the intrinsic base region 108. The first base electrode region 106 is provided separately from the side of the center section 103a. The level of the top of the first base electrode region 106 is substantially identical to the level of the top of the center section 103a.

The extrinsic base region 110 extends from between the second base electrode region 107 and the intrinsic base region 108 to between the second base electrode region 107 and the center section 103a. The combined width of the intrinsic base region 108 and the extrinsic base region 110 is approximately 0.3 to 1.0 μm.

The width of the emitter region 109 is approximately 0.05 to 0.5 μm, preferably approximately 0.05 to 0.2 μm, and more preferably approximately 0.05 to 0.1 μm. A third isolation film 112 is provided on the tops of the intrinsic base region 108, the extrinsic base region 110, and the second base electrode region 107. The third isolation film 112 has a window 111 above the top of the emitter region 109. An emitter electrode region 113 is provided on the top of the third isolation film 112 so as to contact the emitter region 109, via the window 111. The emitter electrode region 113 is an n⁺-type impurity-diffused layer having a higher impurity concentration than the emitter region 109. Note that the tip of the emitter electrode region 113 extends to an outer portion of the window 111 on the top of the third isolation film 112, however the length of the emitter electrode region 113 is not limited.

When the semiconductor device shown in FIG. 1 is activated, a minority carrier is injected into the intrinsic base region 108 by applying a forward biased voltage to the emitter junction plane between the emitter region 109 and the intrinsic base region 108. The carrier is transported by applying a reverse biased voltage to the collector junction plane between the collector region 13, and the intrinsic base region 108 and the extrinsic base region 110.

Here, the tops of the intrinsic base region 108 and the second base electrode region 107 are at substantially the same level. Thus, the junction plane between the second base electrode region 107 and the extrinsic base region 110 is substantially perpendicular in relation to the junction plane between the emitter region 109 and the emitter electrode region 113, and to the junction plane between the collector region 13 and the intrinsic base region 108. Therefore, it is possible to adjust and maintain a junction area X between the second base electrode region 107 and the extrinsic base region 110 at a desired value without any influence of reducing a junction area Y between the emitter region 109 and the emitter electrode region 113, the collector junction area W between the collector region 13 and, the intrinsic base region 109 and the extrinsic base region 110.

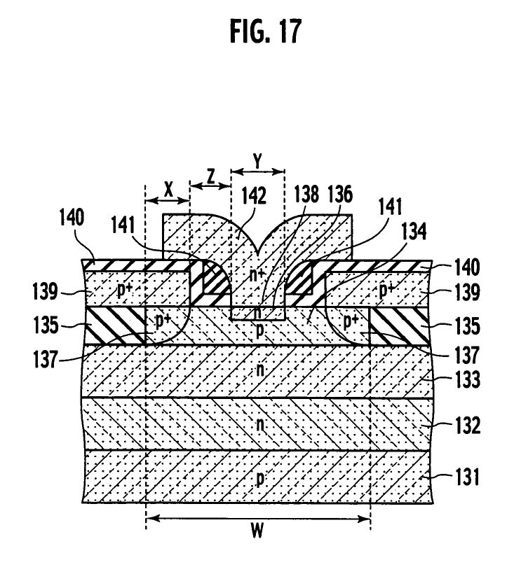

An npn bipolar junction transistor is shown in FIG. 17 as a comparison to the semiconductor device shown in FIG. 1. On the npn bipolar junction transistor shown in FIG. 17, a buried layer 132 is buried in the upper section of a semiconductor substrate 131. A collector region 133 is provided on the buried layer 132. An intrinsic base region 134 is provided on the collector region 133. An emitter region 136 is formed in the upper section of the intrinsic base region 134. An extrinsic base region 137 is formed in the upper section of the intrinsic base region 134. An isolation region 135 is provided on the collector region 133 and surrounds the extrinsic base region 137. A base electrode region 139 is formed on the top of the extrinsic base region 137 and the isolation region 135. A first isolation film 140 and a second isolation film 141 are formed on the upper section and side of the base electrode region 139 and the top of the intrinsic base region 134. An emitter electrode region 142 is formed on the top of the emitter region 136.

On the npn bipolar junction transistor shown in FIG. 17, the base electrode region 139 is provided at a higher location than the level of the top of the intrinsic base region 134. Therefore, the junction plane between the extrinsic base region 137 and the base electrode region 139 is parallel in relation to the junction plane between the collector region 133 and the intrinsic base region 134. Consequently, when the collector junction area W is reduced, it is necessary to also reduce the junction area X between the extrinsic base region 137 and the base electrode region 139, which leads to an increase of base resistance. When the junction area Y of the emitter electrode region 142 and the emitter region 136 is reduced maintain the junction area X between the extrinsic base region 137 and the base electrode region 139 shown in FIG. 17, in order to reduce the collector junction area W, it is necessary to form the sidewalls of the first and second isolation films 140 and 141 at a predetermined width Z. Therefore, there is a limitation in the width Z of the sidewalls when the collector junction area W is reduced while maintaining the junction area X between the extrinsic base region 137 and the base electrode region 139.

According to the semiconductor device shown in FIG. 1, both of the intrinsic base region 108 and the second base electrode region 107 are at the same level. Furthermore, the junctions planes between the second base electrode region 107 and the extrinsic base region 110 are substantially perpendicular in relation to the junction plane between the collector region 13 and the intrinsic base region 108. Therefore, when the collector junction area W is reduced, it is possible to maintain the junction area X between the second base electrode region 107 and the extrinsic base region 110. Therefore, it is possible to reduce feedback capacitance by reducing the collector junction area W and maintaining the junction area X between the base electrode region 107 and the extrinsic base region 110.

Furthermore, according to the semiconductor device shown in FIG. 1, since there is no self-aligning constitution using the sidewalls as shown in FIG. 17, there are no restriction attributes to the width Z of the sidewalls. Therefore, it is possible to improve high frequency characteristics without increasing base resistance.

Furthermore, the extrinsic base region 110 extends from between the base electrode region 14 and the intrinsic base region 108 to between the base electrode region 14 and the collector region 13. Therefore, since the thickness of the junction plane between the extrinsic base region 110 and the base electrode region 14 is thicker than the thickness of the intrinsic base region 108, it is possible to further reduce base resistance than in a base electrode region, which is thinner than the intrinsic base region 108.

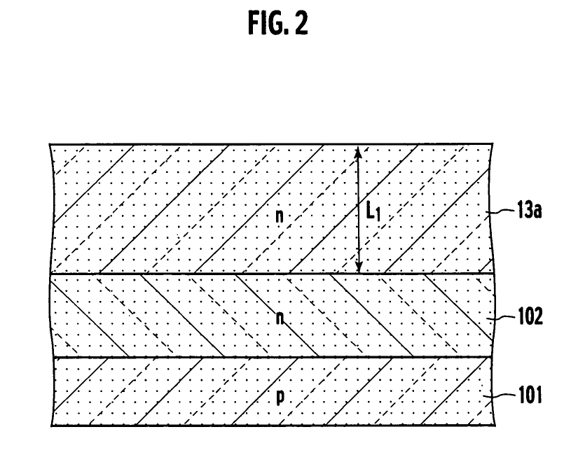

Next, an example of a method for manufacturing the semiconductor device according to the embodiment of the present invention will be described, referring to FIGS. 2 to 11.

First, a semiconductor substrate 101 made of a single crystal p-type silicon is prepared. An buried layer 102 having an n-type is buried in the upper section of the semiconductor substrate 101 by ion implantation with arsenic or the like and heat-treating. Next, a semiconductor layer 103c having an n-type, which will serve as a collector region, is deposited at a first thickness L₁ on the buried layer 102 by epitaxial growth or the like.

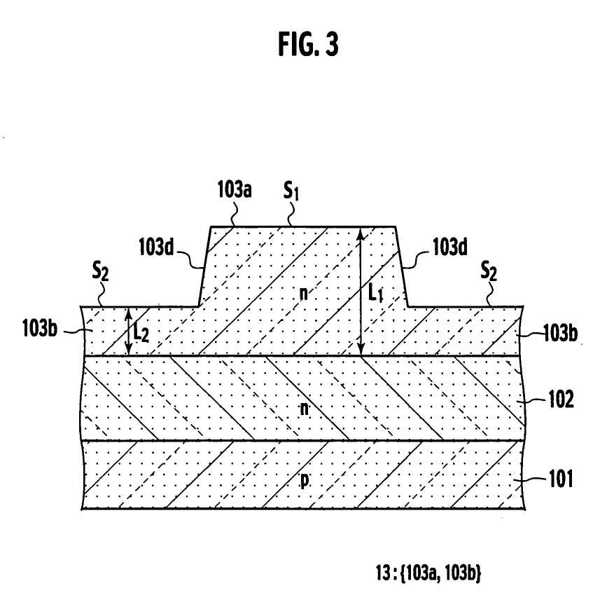

Next, a resist film is spin coated on the semiconductor layer 103c, and an etching mask of the resist is delineated using lithography technology. By reactive ion etching (RIE) or the like in which the etching mask is used, part of the semiconductor layer 103c is selectively eliminated so as to delineate a groove. Here, allowing the center of the semiconductor layer 103c to remain, the region surrounding the center of the semiconductor layer 103c is eliminated. The remaining resist is removed using a resist remover or the like. As a result, a convex collector region 13 is formed having a center section 103a with a first thickness L₁ surrounded by a groove 103d, and a peripheral section 103b with a second thickness L₂ surrounding the center section 103a, as shown in FIG. 3. Note that it is acceptable to form the center section 103a so that the side is perpendicular in relation to the top (first surface) S₁ of the center section 103a. Alternatively, it is also acceptable to form the center section 103a so that the side is diagonally tapered.

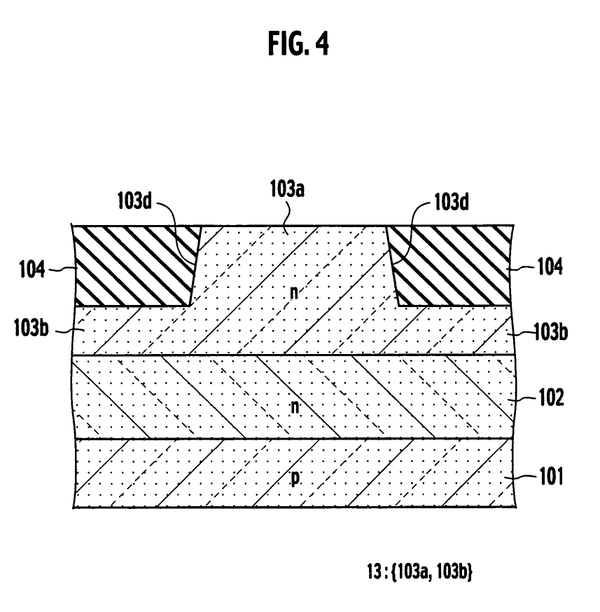

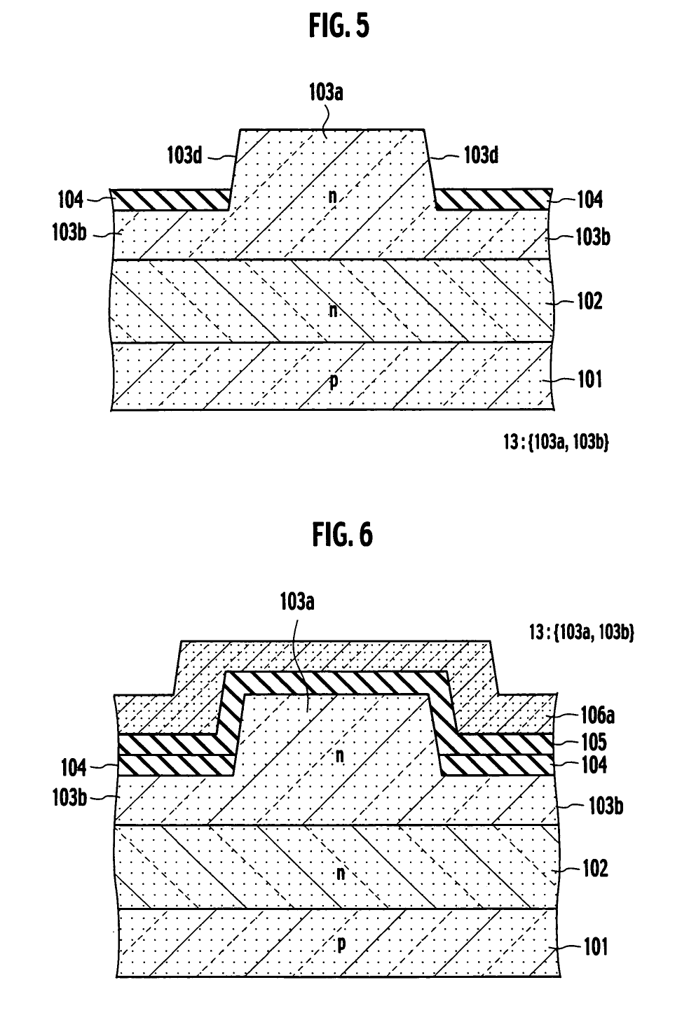

Next, using chemical vapor deposition (CVD) or the like, a first isolation film 104 such as an oxide layer (SiO₂ film) is deposited so as to cover the top of the collector region 13. Then, as shown in FIG. 4, by etching back with wet etching, chemical mechanical polishing (CMP) or the like, the first isolation film 104 is planarized so as to have the top at substantially the same level as the first surface S₁. Thereafter, as shown in FIG. 5, the first isolation film 104 is further etched back using wet etching, RIE or the like. Note that although FIGS. 4 and 5 show an example in which the first isolation film 104 is etched back in two steps, it is also acceptable to etch back the first isolation film 104 in one step.

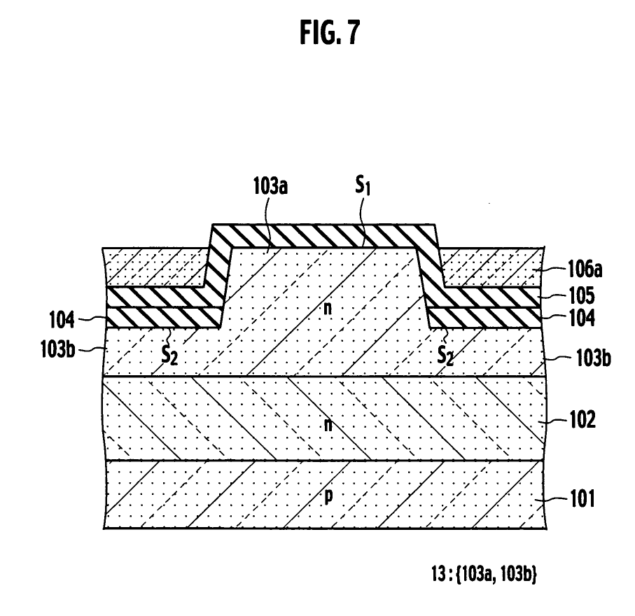

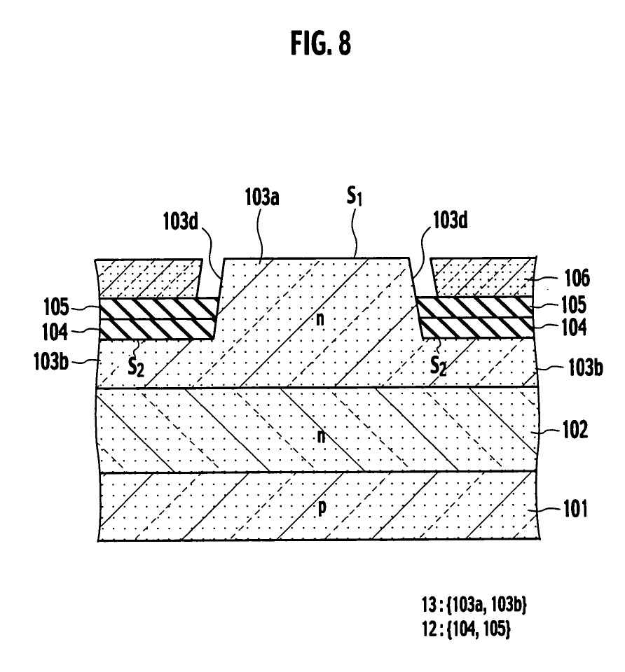

Next, as shown in FIG. 6, using CVD or the like, a second isolation film 105 made of an SiO₂ film or the like, and a polysilicon layer 106, which is to be a first base electrode region, are superimposed so as to cover the first isolation film 104 and the collector region 13. Then, as shown in FIG. 7, using CMP or the like, the top of the polysilicon layer 106a is planarized so as to have substantially the same level as the top (first surface) S₁ of the center section 103a. After that, using wet etching or the like, the second isolation film 105 is selectively eliminated. As a result, shown in FIG. 8, an isolation region 12 including the first and second isolation films 104 and 105 is buried at the bottom of a groove 103d. A first base electrode region 106 is formed on part of the top of the second isolation film 104 and being separated from the side wall of the groove 103d.

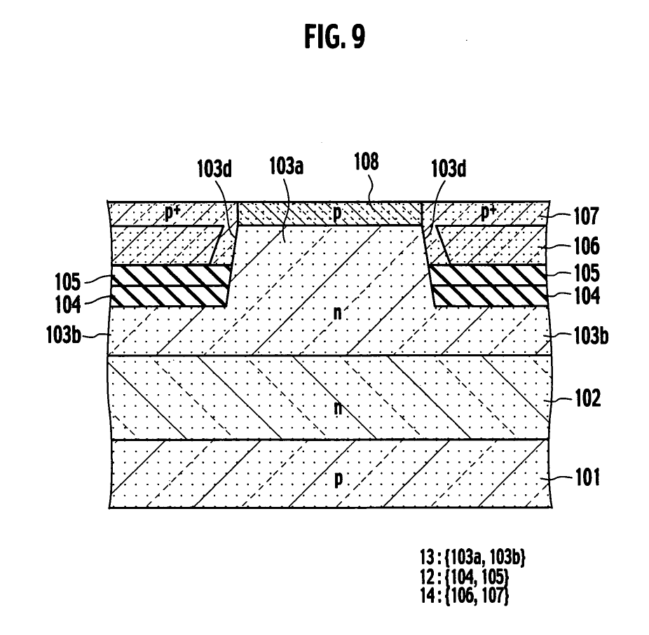

Next, as shown in FIG. 9, by doping epitaxy introducing p-type impurities such as B in the epitaxial layer, an intrinsic base region 108 having a p-type is deposited on and self aligned to the top of the collector region 13. Simultaneously, a second base electrode region 107 having a p⁺-type is deposited on and aligned to the remaining part of the top of the second isolation film 105 and the top of the first base electrode region 106, while contacting the side wall of the groove 103d. Here, the second base electrode region 107 and the intrinsic base region 108 are formed so as to have the top of each at substantially the same level. The second base electrode region 107 is formed so as to have the bottom at a location which is deeper than the bottom of the intrinsic base region 108.

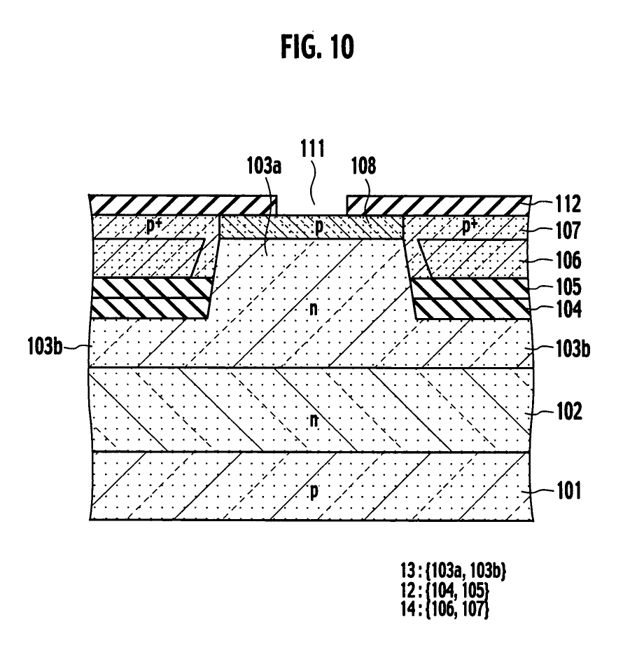

Next, a third isolation film 112 such as SiO₂ film is deposited onto the tops of the second base electrode region 107 and the intrinsic base region 108 by CVD or the like. Then, a resist film is spin coated with the top of the third isolation film 112, and an etching mask of the resist film is delineated using photolithography technology. By RIE or the like in which the etching mask is used, part of the third isolation film 112 is selectively eliminated. As a result, shown in FIG. 10, a window 111 is opened exposing part of the top of the intrinsic base region 108.

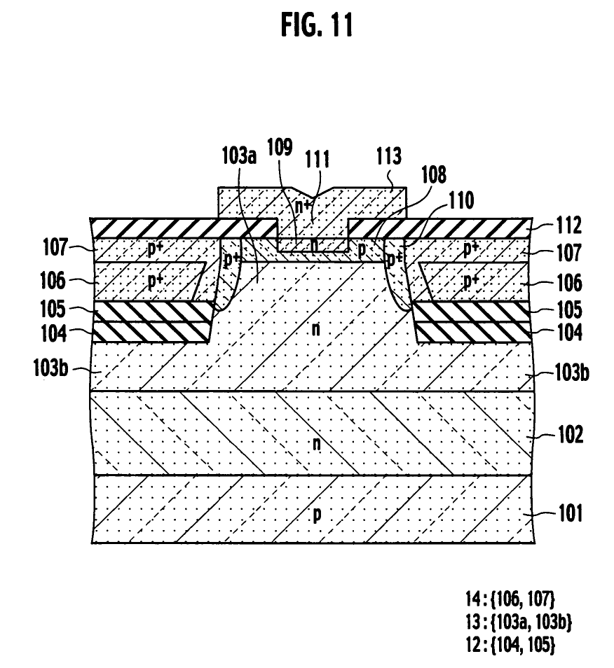

Next, a polysilicon layer is deposited on the top of the intrinsic base region 108 and the third isolation region 112 by CVD or the like. A resist film is spin coated onto the polysilicon layer, and an etching mask of the resist is delineated using photolithography technology. By RIE or the like in which the etching mask is used, part of the polysilicon layer is selectively eliminated. Thereafter, as shown in FIG. 11, an emitter electrode region 113 having an n⁺-type is formed on the polysilicon layer by ion implantation with an n-type impurity such as Arsenic and heat-treating. Simultaneously, an emitter region 109 having an n-type is formed by diffusing n-type impurities in the polysilicon layer.

Also simultaneously, an extrinsic base region 110 having p⁺-type is formed adjacent to the intrinsic base region 108 and the collector region 13 and contacts the second base electrode region 107, by diffusion of the p-type impurities in the second base electrode region 107. The extrinsic base region 110 is formed so as to extend from between the second base electrode region 107 and the intrinsic base region 108 to between the second base electrode region 107 and the collector region 13. It is possible to manufacture the semiconductor device shown in FIG. 1 with the above process. For the example manufacturing method of the semiconductor shown for comparison in FIG. 17, a first isolation film 140 and a second isolation film 141 are formed in the upper section and side of a p-type base electrode region 139. Sidewalls are formed by etching the first and second isolation films 140 and 141. However, it is difficult to control the dimensions of the sidewalls when the sidewalls are miniaturized.

According to the method for manufacturing the semiconductor according to the embodiment of the present invention, the window 111 for exposing the emitter region 109 is formed in the single layer third isolation film 112 shown in FIG. 10 using lithography technology, without forming the sidewalls shown in FIG. 17. Therefore, with advancements in lithography technology, further miniaturization of the junction area Y between the emitter electrode region 113 and the emitter region 109, and the improvement in the alignment precision of the window 111 are possible.

Furthermore, since the base electrode region 14 and the intrinsic base region 108 are formed so that the tops are at substantially the same levels, it is possible to flatly deposit the third isolation film 112 formed on top of the base electrode region 14 and the intrinsic base region 108. Therefore, it is possible to open the window 111 on the third isolation film 112 with a high degree of alignment precision.

The closer the tops of the base electrode region 14 and the intrinsic base region 108 are to being completely flat and even, the more preferable the structure. For instance, using CMP or the like, the first base electrode region 106 and the center section 103a shown in FIG. 8 are planarized so as to have the tops thereof at substantially the same level. Thereafter, the second base electrode region 107 and the intrinsic base region 108 are deposited on the top of the first base electrode region 106 and the collector region 13 so that the tops thereof are at substantially the same levels by epitaxial growth. As a result, it is possible to form the base electrode region 14 and the intrinsic base region 108 so as to have the tops even with each other within a range of 0.05 μm or less.

(Modification)

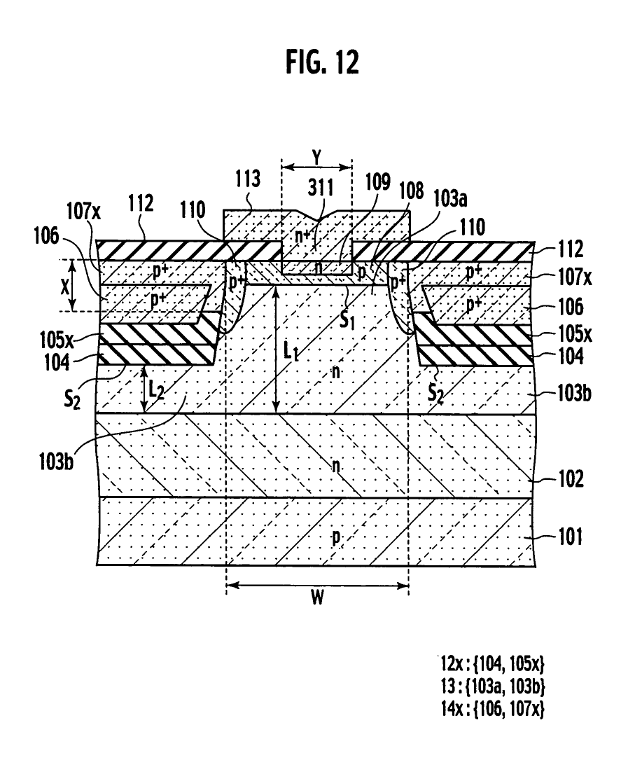

As shown in FIG. 12, a semiconductor device according to a modification of the embodiment of the present invention includes a collector region 13 having a first conductivity type (n-type), an intrinsic base region 108 having a second conductivity type (p-type) provided on the collector region 13, an emitter 109 having an n-type formed in an upper section of the intrinsic base region 108, an isolation region 12x provided on a side of the collector region 13 directly below the intrinsic base region 108, a extrinsic base region 110 having a p⁺-type provided adjacent to the intrinsic base region 108 and having a higher impurity concentration than the intrinsic base region 108, and a base electrode region 14x provided on the top of the isolation region 12 so as to have a region at the same level as the intrinsic base region 108, and contacting the side of the extrinsic base region.

The isolation region 12x includes a first isolation film 104 provided on the top (second surface) L₂ of the peripheral section 103b and contacting the side of the center section 103a, and a second isolation film 105x provided on the top of the first isolation film 104 and contacting the side of the center section 103a.

The base electrode region 14x includes a first base electrode region 106 provided on part of the top of the second isolation film 105 and being separated from the extrinsic base region 110, and a second base electrode region 107x provided on the remaining part of the top of the second isolation film 105 and on the top of the first base electrode region 106 and in contact the extrinsic base region 110. The second base electrode region 107x has a region at the same level as the intrinsic base region 108.

Here, the remaining part of the top of the second isolation film 105x extends to between the collector region 13 and the first base electrode region 106 in the direction toward the top of the collector region 13 (the direction pointing toward the location of the intrinsic base region 108), and differs from the semiconductor device shown in FIG. 1. Therefore, the junction area X′ between the extrinsic base region 110 and the second base electrode region 107x is thinner than the junction area X shown in FIG. 1.

According to the modification of the embodiment of the present invention, the same as in the embodiment, it is possible to maintain the junction area X′ between the second base electrode region 107 and the extrinsic base region 110 when the collector area W between the collector region 13 and the intrinsic base region 108 is reduced. Therefore, it is possible to improve high frequency characteristic without increasing base resistance.

Furthermore, it is possible to adjust the junction area X′ between the extrinsic base region 110 and the second base electrode region 107x by adjusting the length (thickness) of the second isolation film 105x between the collector region 13 and the first base electrode region 106, and therefore it is possible to adjust collector-base capacitance.

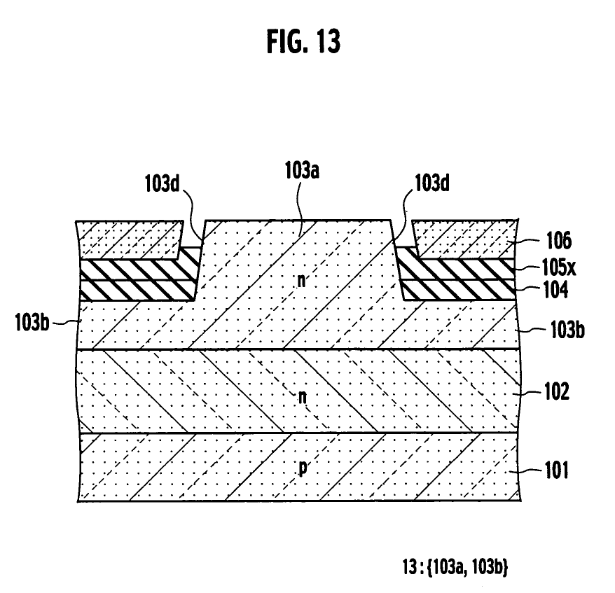

In the method for manufacturing the semiconductor shown in FIG. 12, instead of the procedure shown in FIG. 8, as shown in FIG. 13, part of the second isolation film 105x formed at the side of the first base electrode region 106 is eliminated by wet etching the second isolation film 105x. It is possible to adjust the junction area X′ between the extrinsic base region 110 and the second base electrode region 107x by maintaining the second isolation film 105x between the side of first base electrode region 106 and the side of the center section 103a, and therefore it is possible to adjust collector-base capacitance. Apart from the above, the method for manufacturing the semiconductor device according to the modification is substantially the same as that of the embodiment shown in FIGS. 2 to 11, and thus a redundant description will be omitted.

(Other Embodiment)

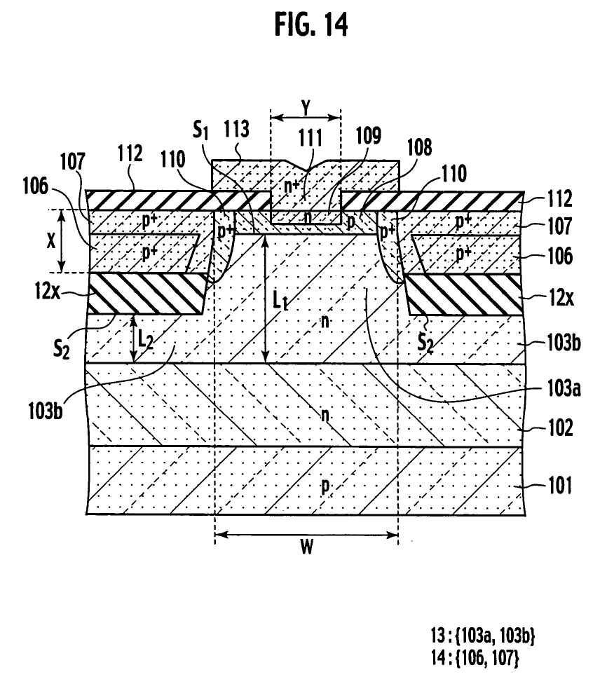

As to the embodiment, although FIG. 1 shows the isolation region 12 including a first and second isolation film 104 and 105 in order to reduce collector-base parasitic capacitance, it is also acceptable to use a single layer isolation region 12x shown in FIG. 14 instead of the isolation region 12.

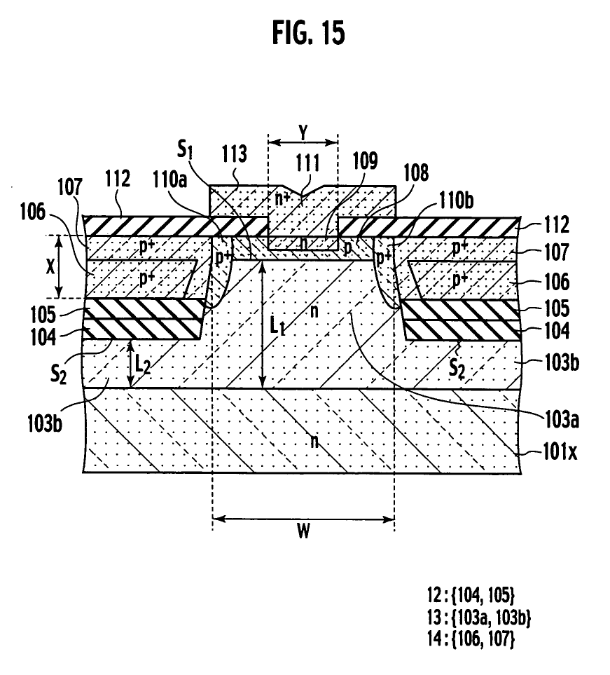

Furthermore, although FIG. 1 shows an example of a collector region 13 provided on the top of the n-type buried layer 102, it is also acceptable to form the n-type collector region 13 on the top of the n-type Si of other type of semiconductor substrate 101, as shown in FIG. 15. In FIG. 15, it is acceptable to extend a collector electrode from the bottom of the semiconductor substrate 101x.

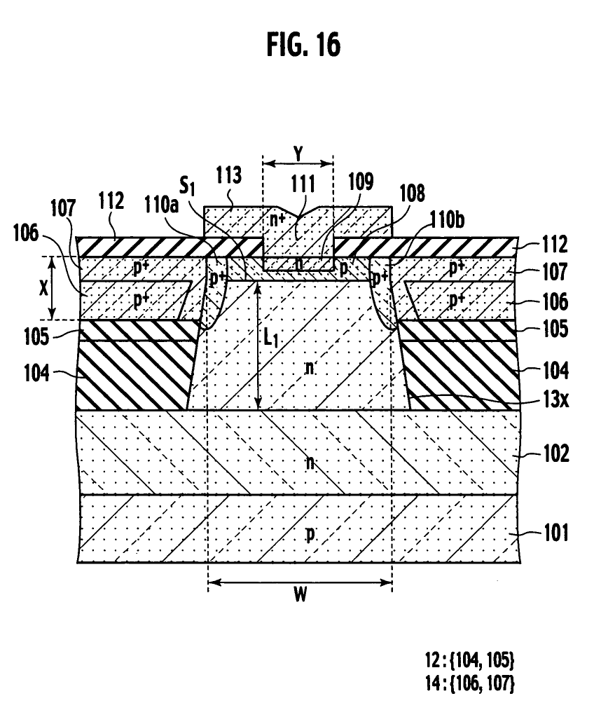

Furthermore, although FIG. 1 shows the convex collector region 13 including the center section 103a and the peripheral section 103b, the collector region 13 is not limited to a convex form. For instance, as shown in FIG. 16, a collector region 13x which has a rectangular shape has only the center section 103a, omitting the peripheral section 103b shown in FIG. 1. As for the method for manufacturing the semiconductor device shown in FIG. 16, part of the semiconductor layer 103c is eliminated until the buried layer 102 is exposed, as in the procedure shown in FIG. 3.

Apart from the above, the method of the modification is substantially the same as that of the embodiment shown in FIGS. 2 to 11, and thus a redundant description will be omitted.

Various modifications will become possible for those skilled in the art after receiving the teachings of the present disclosure without departing from the scope thereof.

1. A semiconductor device comprising:
a collector region having a first conductivity type;
an intrinsic base region having a second conductivity type provided on the collector region;
an emitter region having the first conductivity type formed in an upper section of the intrinsic base region;
an isolation region provided on a side of the collector region directly under the intrinsic base region;
an extrinsic base region having the second conductivity type provided adjacent to the intrinsic base region, and having a higher impurity concentration than the intrinsic base region; and
a base electrode region provided on the isolation region, and contacting a side of the extrinsic base region so as to have a region at the same level as the intrinsic base region.

2. The semiconductor device of claim 1, wherein the collector region comprises:
a center section having the top thereof corresponding to the bottom of the intrinsic base region; and
a peripheral section contacting to the center section surrounding the center section, and having the top thereof corresponding to the bottom of the isolation region.

3. The semiconductor device of claim 1, wherein the collector region is convex, and comprises:
a center section contacting the bottom of the intrinsic base region; and
a peripheral section contacting to the center section surrounding the center section, and having a thickness which is thinner than the center section.

4. The semiconductor device of claim 1, wherein the bottom of the base electrode region is located deeper than the bottom of the intrinsic base region, and the extrinsic base region extends from between the base electrode region and the intrinsic base region to between the base electrode region and the collector region.

5. The semiconductor device of claim 1, wherein a junction plane between the extrinsic base region and the base electrode region is substantially perpendicular to a junction plane between the collector region and the intrinsic base region.

6. The semiconductor device of claim 3, wherein the isolation region comprises:
a first isolation film provided on the peripheral section and contacting a side of the center section; and
a second isolation film provided on the first isolation film and contacting the side of the center section.

7. The semiconductor device of claim 1, wherein the base electrode region comprises:
a first base electrode region provided on part of the top of the isolation region and being separated from the extrinsic base region; and
a second base electrode region provided on a remaining part of the top of the isolation region and the top of the first base electrode region, contacting the extrinsic base region, so as to have a region at the same level as the intrinsic base region.

8. The semiconductor device of claim 7, wherein the bottom of the second base electrode region is located deeper than the bottom of the intrinsic base region, and the extrinsic base region extends from between the second base electrode region and the intrinsic base region to between the second base electrode region and the collector region.

9. The semiconductor device of claim 7, wherein the remaining part of the isolation region extends to between the collector region and the first base electrode region, in a direction toward the outskirt of the intrinsic base region.

10. A method for manufacturing a semiconductor device, comprising:
depositing a semiconductor layer having a first conductivity type on a semiconductor substrate;
forming a groove by selectively eliminating part of the semiconductor layer, and defining the semiconductor layer surrounded by the groove as at least part of a collector region;
burying an isolation region at the bottom of the groove;
forming an intrinsic base region having a second conductivity type on the collector region surrounded by the groove;
forming a base electrode region at the groove on the isolation region;
forming an emitter region having the first conductivity type in an upper section of the intrinsic base region; and
forming an extrinsic base region having the second conductivity type adjacent to the intrinsic base region, having a higher impurity concentration than the intrinsic base region, so as to contact a side of the base electrode region.

11. The method of claim 10, wherein burying the isolation region comprises:
burying a first isolation film at the groove; and
burying a second isolation film at the groove on the first isolation film.

12. The method of claim 10, wherein forming the base electrode region comprises forming the base electrode region so as to have the top thereof at substantially the same level as the intrinsic base region.

13. The method of claim 10, wherein forming the base electrode region comprises:
forming a first base electrode region on part of the top of the isolation region being separated from side wall of the groove; and
forming a second base electrode region on a remaining part of the top of the isolation region and the top of the first base electrode region so as to contact a side of the groove.

14. The method of claim 13, wherein forming the first base electrode region comprises forming the first base electrode region so that the top thereof is at substantially the same level as at least the part of the collector region.

15. The method of claim 13, wherein forming the second base electrode region comprises forming the bottom of the second base electrode region deeper than the bottom of the intrinsic base region.

16. The method of claim 15, wherein forming the extrinsic base region comprises forming the extrinsic base region so as to extend from between the second base electrode region and the intrinsic base region to between the second base electrode region and the collector region.

17. The method of claim 10, wherein forming the second base electrode region comprises forming the second base electrode region simultaneously with the forming of the intrinsic base region.

18. The method of claim 10, wherein forming the base electrode region comprises forming the bottom of the base electrode region deeper than the bottom of the intrinsic base region.

19. The method of claim 18, wherein forming the extrinsic base region comprises forming the extrinsic base region from between the base electrode region and the intrinsic base region to between the base electrode region and the collector region.

20. The method of claim 11, wherein forming the emitter region comprises:
depositing a third isolation film on the top of the intrinsic base region;
opening a window at part of the third isolation so as to expose part of the intrinsic base region; and
forming the emitter region in the upper section of the intrinsic base region through the window.
